(19) United States
(12) Patent Application Publication
(10) Pub. No.: US 2015/0364374 A1
(43) Pub. Date: Dec. 17, 2015

(54) Semiconductor Device Die Singulation by Discontinuous Laser Scribe and Break

(71) Applicant: Toshiba Corporation, Tokyo (JP)

(72) Inventors: Norihito Hamaguchi, Morgan Hill, CA (US); Chao-Kun Lin, San Jose, CA (US)

(73) Assignee: Toshiba Corporation

(21) Appl. No.: 14/303,345

(22) Filed: Jun. 12, 2014

(51) Int. Cl. H01L 21/78; H01L 23/544; H01L 29/04; H01L 21/268

(52) U.S. Cl. CPC H01L 21/78; H01L 21/268; H01L 23/544; H01L 29/04

(57) ABSTRACT

A method for singulating a semiconductor device dies from a wafer, and a singulated semiconductor device die is disclosed. In one embodiment, the method includes forming a plurality of recesses in a surface of the wafer along the edges of the semiconductor device dies to be singulated, each of the recesses having a tapered inner surface. The method further includes applying pressure to an opposite surface of the wafer along the edges of the semiconductor device dies, separating the edges of the semiconductor device dies from the wafer. In one embodiment, the recesses are formed by a pulsed laser. In one embodiment, the pressure is applied by a wafer breaking machine.

### FIELD OF THE INVENTION

The invention relates generally to a method for singulating individual semiconductor device dies from a wafer.

### BACKGROUND OF THE INVENTION

Modern semiconductor device dies begin by forming layers of semiconductor materials on top of a wafer. The wafer varies in thickness and in diameter, and typically ranges from 300 μm to 1 mm in thickness and 1 inch to 18 inches in diameter. The size and thickness of the wafer will depend on the type of semiconductor device die being created. For example, light emitting diodes (LEDs) will typically be manufactured on wafers ranging from 2 inches to 6 inches in diameter and the wafer thickness is reduced at the end of wafer processing to 150 μm to 250 μm in thickness before die singulation. The wafer will undergo many microfabrication processes to form the semiconductor device die, such as doping, ion implantation, etching, deposition, and photolithographic patterning. Once the semiconductor device dies are formed on the wafer, the wafer will be diced to singulate the individual semiconductor device dies from the wafer so that they can be packaged and further incorporated into lighting appliances and various electronic devices such as mobile phones and cameras.

There are two general methods for singulating a semiconductor device die: 1) a “full-thickness” singulation, and 2) a “scribe and break” singulation. A “full-thickness” singulation involves cutting through the wafer along the edges of the individual semiconductor device die using a mechanical saw or a high-powered laser. A “scribe and break” singulation involves scribing a trench on the surface of the wafer along the edges of the individual semiconductor device die using a mechanical saw or a high-powered laser, and then applying pressure to the opposite surface of the wafer using a breaking machine to separate the individual die along the scribed trenches formed by the mechanical saw or the high-powered laser. Typically a breaking machine comprises a sharp blade which applies a focused, uniform pressure to the wafer.

In either method, the mechanical saw uses a rotating diamond-impregnated blade and relies on the diamond particles embedded in the blade to break away small amounts of silicon, metals, dielectric materials, and other compounds forming the substrate on which the semiconductor device dies are fabricated. Optimizing the processes using the mechanical saw requires finding the balance between several competing considerations. One such consideration is optimizing the cutting speed and the rotation speed of the mechanical saw. If the rotation speed is too high for a given material at a given cutting speed, the mechanical saw will cause chipping and cracking of the semiconductor device die. In extreme cases delaminating the semiconductor layers from the wafer, which may cause the semiconductor device to become defective or non-functional, reducing the overall yield of usable die per wafer. Lowering the rotation speed of the mechanical saw will increase the wear on the diamond blade and may ultimately cause the diamond blade to break faster, leading to increased downtime during the fabrication process to replace the diamond blade. Both downtime and blade replacement will increase overall fabrication time and cost. If the rotation speed of the mechanical saw is too low, the mechanical saw will again cause chipping and cracking of the semiconductor device die.

There are some disadvantages to using a mechanical saw for singulating semiconductor device die as well. By breaking away small amounts of the silicon, metals, and other semiconductor compounds, the mechanical saw introduces large quantities of particulate matter into the fabrication environment. Since modern semiconductor device die fabrication occurs in a “clean-room” environment, the use of the mechanical saw can easily lead to contamination of the fabrication environment. Additionally, the diamond blade must constantly be lubricated and cooled by a stream of water. Water is also used to wash away particulate matter generated by the diamond blade cutting through the wafer, in order to reduce contamination of the fabrication environment. Large-scale semiconductor device die singulation by mechanical saw operations will consume substantial amounts of water, which increases the overall fabrication cost.

To address some of the problems with semiconductor device die singulation using the mechanical saw, manufacturers began using high-powered lasers in both the “full-thickness” and “scribe and break” semiconductor device die singulation. Like the mechanical saw, the high-powered laser will cut continuously along the edges of the semiconductor device dies on the wafer to singulate the individual semiconductor device die. Unlike the mechanical saw, however, the high-powered laser will ablate the materials it is cutting through, generating only small amounts of debris particles, and does not require any water during the singulation process (also known as a “dry-process”). Additionally, by using high-powered lasers rather than a mechanical saw that places the wafer in contact with a physical blade rotating at high speeds exerting shearing force and vibrations, laser-based singulation processes are less likely to cause mechanical stress on the semiconductor device die being singulated. Mechanical stress can lead to delamination of metal electrodes and dielectric films, which can result in long-term reliability issues.

There are also some disadvantages to the use of a high-powered laser to singulate the semiconductor device dies. First, “full-thickness” and “scribe and break” singulation by high-powered laser can be much slower than the mechanical blade because the laser must penetrate into the wafer layer-by-layer, and some materials require increased exposure to the laser to ablate the material. If the laser power is increased to improve the singulation speed, there is an increased risk of heat damage to the semiconductor device die and the wafer.

Second, the reason that the laser does not generate large amounts of particulate matter released into the air is because the amount of the material removed is typically significantly less than that of the mechanical saw. The use of the mechanical saw usually results in a cut that is 10% to 20% wider than the thickness of the blade. The high-powered laser will focus energy on a small region, which results in ablation as well as rapid heating and melting of the material causing small amounts of debris to be ejected. Some of the debris will be re-deposited onto the surface of the semiconductor device die. Very often the debris will cover 10 μm or more of the surface of the semiconductor device die from the edges that were cut by the high-powered laser. This is especially problematic for LEDs because the debris will block or absorb some of the light emitted from the LED, reducing the overall light output of the device. The sidewalls along the edges of the singulated semiconductor device die will also be extremely rough because the high-powered laser essentially melts through the layers of the wafer, causing an uneven cut compared to the use of a diamond blade mechanical saw. Again, this will be especially problematic for LEDs because the rough sidewalls will reflect less light than smooth sidewalls, and thus will absorb more light and reduce the overall light output of the LED.

Third, the use of a laser to continuously cut through the wafer is not suitable for singulating semiconductor device die formed on certain types of wafers, such as silicon (Si). The laser will cause the silicon to melt, then re-solidify as it cools, filling in the continuous scribe trenches or cut lines that were previously created by the laser. In effect, it is as if the trench or cut was never made.

### BRIEF DESCRIPTION OF THE INVENTION

In one embodiment, a method for singulating a semiconductor device die from a wafer includes forming a plurality of recesses in a surface of the wafer along the edges of the semiconductor device die to be singulated. In one embodiment, the wafer comprises a single crystalline substrate. In another embodiment, the wafer comprises a poly-crystalline substrate. In another embodiment, the wafer comprises an amorphous semiconductor substrate. In yet another embodiment, the wafer comprises a ceramic substrate. In yet another embodiment, the wafer comprises a composite substrate that includes a variety of materials.

In one embodiment, each of the plurality of recesses formed in the surface of the wafer have a tapered inner surface, and extends to a depth between 5% and 75% of the thickness of the wafer. In one embodiment, each of the plurality of recesses is formed at least 1 μm away from an adjacent recess. In one embodiment, the method further includes applying pressure to a surface of the wafer opposite the surface having the plurality of recesses formed therein. The pressure is applied along the edges of the semiconductor device die, separating the edges of the semiconductor device die from the wafer.

In one embodiment, the plurality of recesses are formed by a pulsed laser. In one embodiment, the pressure is applied by a wafer breaking machine.

In one embodiment, a singulated semiconductor device die includes a first major surface and a second major surface. The semiconductor device die further includes a plurality of sidewalls along the periphery of the die and perpendicular to the first and second major surfaces. In one embodiment, the semiconductor device die comprises a single crystalline substrate. In another embodiment, the semiconductor device die comprises a poly-crystalline substrate. In another embodiment, the semiconductor device die comprises an amorphous semiconductor substrate. In yet another embodiment, the semiconductor device die comprises a ceramic substrate. In yet another embodiment, the semiconductor device die comprises a composite substrate.

The semiconductor device die further includes a plurality of recesses formed in at least one of the sidewalls, in a direction perpendicular to the first and second major surfaces, each of the plurality of recesses having a tapered inner surface. In one embodiment, the plurality of recesses formed in the sidewall have a depth between 5% and 75% of the overall die thickness. In one embodiment, the plurality of recesses are formed at least 1 μm away from an adjacent recess. In one embodiment, the plurality of recesses are formed by a pulsed laser.

### BRIEF DESCRIPTION OF THE FIGURES

FIG. 1 shows a plan view of a wafer with a plurality of semiconductor device die formed therein.

FIG. 2 shows an expanded view of the wafer in FIG. 1 with a plurality of recesses formed in the wafer along an edge of the individual semiconductor device dies to be singulated.

FIG. 3 shows a profile-view of a singulated semiconductor device die with a plurality of recesses formed in the surface along the edge of the die.

FIG. 4 shows a plot of the quality of the scribe and break singulation method as a function of the relationship between the depth of the plurality of recesses formed in the surface of the wafer and the distance between them.

### DETAILED DESCRIPTION OF THE INVENTION

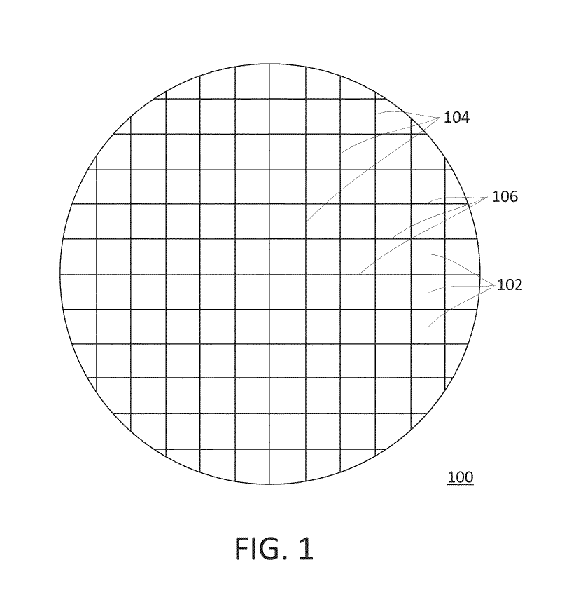

FIG. 1 shows a plan view of a wafer with a plurality of semiconductor device dies formed therein. In FIG. 1, wafer 100 comprises a plurality of semiconductor die 102. Each of the semiconductor device dies 102 is delineated from the other dies along edges 104 and 106. In order to be packaged and sold, each of the semiconductor device dies 102 must be singulated from wafer 100. In one embodiment, the wafer 100 is between 1 inch and 18 inches in diameter, and 100 μm to 1 mm in thickness.

In one embodiment, the wafer 100 comprises a single crystalline substrate, such as single crystalline silicon carbide (SiC), single crystalline zinc oxide (ZnO), single crystalline silicon (Si), etc. In another embodiment, the wafer 100 comprises a poly-crystalline substrate, such as polycrystalline silicon (poly-Si), polycrystalline diamond (PCD), polycrystalline aluminum nitride (poly-AlN), polycrystalline zinc oxide (poly-ZnO), etc. In yet another embodiment, the wafer 100 comprises an amorphous semiconductor material, such as amorphous gallium arsenide (a-GaAs), amorphous germanium (a-Ge), amorphous silicon (a-Si), amorphous silicon carbide (a-SiC), etc. In yet another embodiment, the wafer 100 comprises a ceramic, such as alumina (Al₂O₃), aluminum nitride (AlN), silica (Si0₂), etc. In yet another embodiment, wafer 100 comprises a composite substrate including a variety of crystalline, amorphous, and ceramic materials.

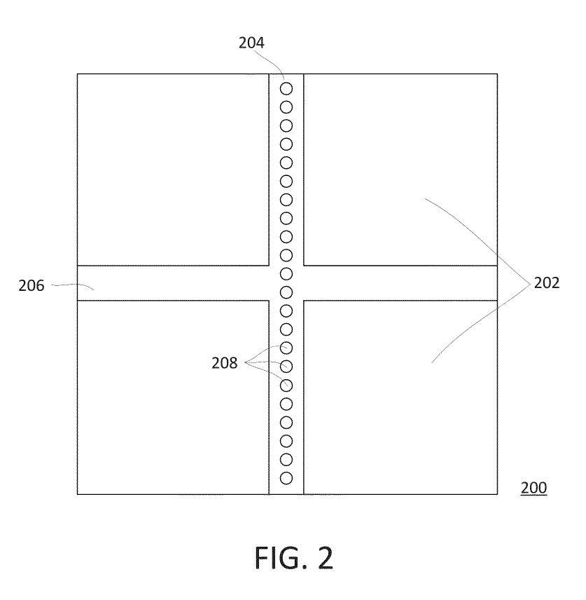

FIG. 2 shows an expanded view of the wafer in FIG. 1 with a plurality of recesses formed in the wafer along an edge of the individual semiconductor device dies to be singluated. In FIG. 2, individual semiconductor device dies 202 are separated by dicing streets 204 and 206, which run along the edges of the individual semiconductor device dies 202. A plurality of recesses 208 are formed in a first major surface of the wafer 200, along the dicing streets 204 and 206, and the edges of the individual semiconductor device dies 202. In one embodiment, the recesses are formed using a pulsed UV laser, such as a diode-pumped solid-state laser (DPSS) having a constant repetition rate and spot size.

After the plurality of recesses 208 are formed, a breaking machine applies pressure to a surface of the wafer 200 opposite the recesses 208, along the dicing streets 204 and 206 of the semiconductor dies 202. Because the recesses 208 form a weak point in the wafer 200, the pressure from the breaking machine will cause a cleavage plane substantially perpendicular to the major surfaces of the wafer 200 to be formed along the recesses 208, following the dicing streets 204 and 206, separating the wafer. In one embodiment, the plurality of recesses 208 are formed along each dicing street 204 and 206 of the wafer 200 before applying pressure from the breaking machine.

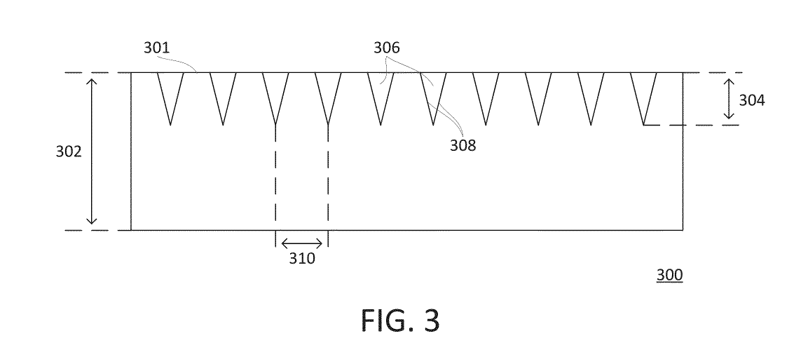

FIG. 3 shows a profile-view of a singulated semiconductor device die with a plurality of recesses formed in a surface along the edge of the die. In FIG. 3, singulated semiconductor device die 300 has a thickness 302, and has a plurality of recesses 306 formed in a first major surface 301. Each of the recesses 306 has a depth 304 and a tapered inner surface 308. Each of the recesses 306 is separated from the next adjacent recess 306 by a distance, or pitch 310. Pitch 310 is measured from the center of the adjacent recesses 306. In one embodiment, the depth 304 is between 5% and 75% of the thickness 302 of wafer 300. In one embodiment the pitch 310 is greater than 1 μm.

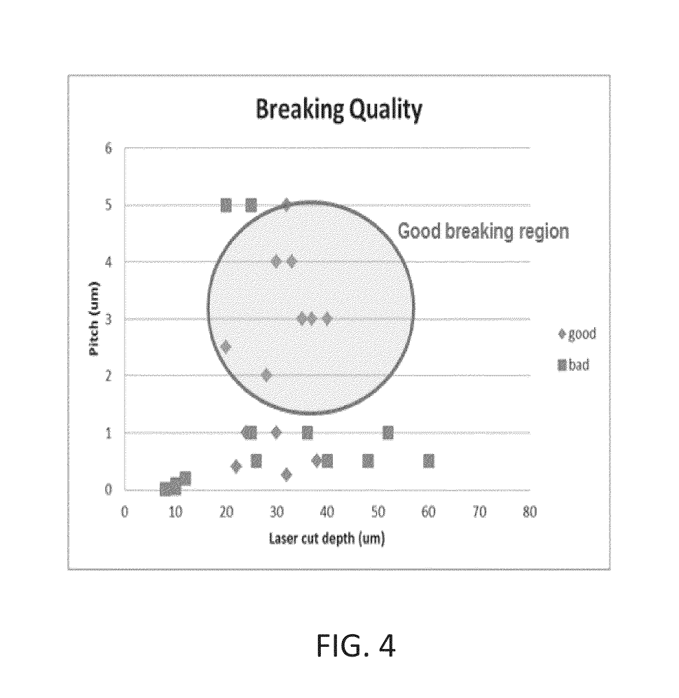

FIG. 4 shows a plot of the quality of the scribe and break singulation method as a function of the relationship between the depth of the plurality of recesses formed in the surface of the wafer and the distance between them. In FIG. 4, a standard single crystalline silicon (Si) wafer was thinned down to 150 μm in thickness. A plurality of recesses were formed in the surface of the wafer along the dicing streets. For each dicing street, the pitch and the depth of the plurality of recesses were varied to determine the quality of the scribe and break singulation method at various depths and pitches. A good quality scribe and break singulation occurs when the semiconductor device die separates along the dicing street, following the plurality of recesses that were formed. A bad quality scribe and break singulation occurs when the semiconductor device die separates off of the dicing street, deviating away from the plurality of recesses that were formed.

As shown in FIG. 4, a pitch of between 2 μm and 4 μm with a depth between 20 μm and 40 μm produced consistently good quality scribe and break singulation of the 150 μm thickness single crystalline silicon (Si) wafer. An in-depth analysis of the data also reveals certain trends between the pitch and depth of the recesses and the quality of the singulation process.

TABLE 4-1
Small Pitch

| | | | | |
|---|---|---|---|---|
| Pitch (μm) | 2.0 | 1.0 | 0.40 | 0.20 |
| Depth (μm) | 28 | 30 | 22 | 12 |
| Singulation | good | good | good | bad |

In table 4-1, it can be seen that forming the recesses too close together will produce a bad quality scribe and break singulation. Below a pitch of 0.20 μm, the plurality recesses are formed so close together that, in effect, they are no longer distinct from adjacent recesses. The laser is essentially performing a continuous scribe along the dicing street similar to prior art methods, which as previously discussed, are not suitable for certain types of wafers such as silicon (Si). The laser will cause the silicon to melt, then re-solidify as it cools, filling in the continuous scribe trenches or cut lines that were previously created by the laser. In effect, it is as if the trench or cut was never made.

TABLE 4-2
Shallow Depth

| | Pitch (μm) | | | | | |
|---|---|---|---|---|---|---|
| | 0.02 | 0.05 | 0.1 | 0.2 | 0.5 | 1.0 |
| Depth (μm) | 10 | 10 | 10 | 10 | 10 | 10 |
| Singulation | bad | bad | bad | bad | bad | bad |

In table 4-2, it can be seen that if the plurality of recesses are not formed deep enough into the wafer, then this will also produce a bad quality scribe and break singulation. At a depth of 10 μm, the plurality of recesses have not penetrated deep enough into the wafer to form a weak point in the wafer, so that when the pressure from the breaking machine is applied the cleavage plane will not follow the plurality of shallow recesses, resulting in a bad quality scribe and break singulation.

TABLE 4-3
Increasing Pitch, Decreasing Depth

| | | | | | |
|---|---|---|---|---|---|
| Pitch (μm) | 0.25 | 0.50 | 1.0 | 2.5 | 5.0 |
| Depth (μm) | 32 | 38 | 24 | 20 | 20 |
| Singulation | good | good | good | good | bad |

In table 4-3, and as shown in FIG. 4, it can be seen that a combination of sufficient depth and pitch of the plurality of recesses formed in the surface of the wafer will result in consistently good quality scribe and break singulation. It can also be seen that when the pitch of the plurality of recesses is too large, for example 5 μm, even if the depth of the recesses is otherwise sufficient, the plurality of recesses does not form a sufficient weak point in the wafer along the dicing streets which will allow for a good quality scribe and break singulation.

It should also be noted that increasing the depth of the plurality of recesses may, in some instances, compensate for the small pitch between adjacent recesses. In table 4-3, a plurality of recesses with a pitch of 0.25 μm and a depth of 32 μm produced a good quality scribe and break singulation. However, as shown in FIG. 4, the quality of the scribe and break singulation at such small pitches are inconsistent at best, and thus unsuitable for commercial wafer singulation.

While FIG. 4 and tables 4-1 through 4-3 are based upon a single crystalline silicon (Si) wafer having a thickness of 150 μm, the quality of the scribe and break singulation process as a function of the relationship between the depth of the plurality of recesses formed in the wafer and the distance between them, according to one embodiment of the invention, will be similar for all other types of wafers, including other single-crystalline substrate, poly-crystalline substrates, amorphous semiconductor substrates, and ceramic substrates. The pitch and depth of the plurality of recesses must be sufficient to form a weak point in the wafer to produce a cleavage plane that follows the plurality of recesses along the dicing street. If the depth is too shallow or the pitch is too small or too big, then the quality of the scribe and break singulation will be bad, or at best, inconsistent.

There are a number of benefits to singulating semiconductor device die by forming a plurality of recesses with a laser in the surface of the wafer along the dicing streets or edges of the semiconductor device dies to be singulated. The use of a laser addresses the disadvantages to mechanical saw singulation, including eliminating the need to replace costly diamond saw blades and the use of large quantities of water to cool the blade and reduce the amount of particulate matter released into the fabrication environment. Additionally, by forming a plurality of recesses in the surface of the wafer with the laser, rather than continuously cutting through the wafer or continuously forming a trench in the wafer, the scribe and break singulation according to one embodiment of the invention will reduce the amount of time required to singulate the semiconductor device dies from the wafer.

Additionally, because only a plurality of recesses are formed in the surface of the wafer, there will be less debris that is deposited onto the surface of the semiconductor device die, and the edges of the semiconductor device die will be smoother as there will be less scarring caused by the plurality of recesses as compared to a continuous cut by the laser. As previously mentioned, for certain types of semiconductor devices, such as LEDs, smooth edges and reduced debris on the surface will result in improved overall light output and efficiency. Additionally, the possibility of heat damage to the semiconductor device die is reduced. Thus, not only will the yield be improved by singulating the semiconductor device dies by forming a plurality of recesses in the surface of the wafer, but the quality and performance of the semiconductor device die will be improved as well.

Other objects, advantages and embodiments of the various aspects of the present invention will be apparent to those who are skilled in the field of the invention and are within the scope of the description and the accompanying Figures. For example, but without limitation, structural or functional elements might be rearranged, or method steps reordered, consistent with the present invention. Principles according to the present invention, and methods and systems that embody them, could be applied to other examples, which, even if not specifically described here in detail, would nevertheless be within the scope of the present invention.

1. A method of singulating a semiconductor device die from a wafer, the method comprising:
forming a plurality of recesses in a surface of the wafer in a dicing street direction along the edges of the semiconductor device die to be singulated, each of the plurality of recesses being spaced apart from an adjacent recess in the range of 1.5 μm to 4 μm and having a tapered inner surface; and
applying pressure to an opposite surface of the wafer along the edges of the semiconductor device die, separating the edges of the semiconductor device die from the wafer.

2. The method according to claim 1 wherein the recesses are formed by a pulsed laser.

3. The method according to claim 1 wherein the pressure is applied by a wafer breaking machine.

4. (canceled)

5. The method according to claim 1 wherein each of the plurality of recesses formed having a depth between 5% and 75% of the wafer thickness.

6. The method according to claim 1 wherein the wafer comprises a single crystalline substrate.

7. The method according to claim 1 wherein the wafer comprises a poly-crystalline substrate.

8. The method according to claim 1 wherein the wafer comprises an amorphous semiconductor substrate.

9. The method according to claim 1 wherein the wafer comprises a ceramic substrate.

10. The method according to claim 1 wherein the wafer comprises a composite substrate.

11. A singulated semiconductor device die comprising:
a first major surface and a second major surface;
a plurality of sidewalls along the periphery of the die substantially perpendicular to the first and second major surfaces; and
wherein at least one of the sidewalls having a plurality of recesses formed therein in a direction perpendicular to the first and second major surfaces, each of the plurality of recesses being spaced apart from an adjacent recess in the range of 1.5 μm and 4 μm and having a tapered inner surface.

12. The singulated semiconductor device die of claim 11 wherein the plurality of recesses is formed by a pulsed laser.

13. (canceled)

14. The singulated semiconductor device die of claim 11 wherein the plurality of recesses have a depth between 5% and 75% of the singulated semiconductor device die thickness.

15. The singulated semiconductor device die of claim 11 further comprising a single crystalline substrate.

16. The singulated semiconductor device die of claim 11 further comprising a poly-crystalline substrate.

17. The singulated semiconductor device die of claim 11 further comprising an amorphous semiconductor substrate.

18. The singulated semiconductor device die of claim 11 further comprising a ceramic substrate.

19. The singulated semiconductor device die of claim 11 further comprising a composite substrate.

20. The method according to claim 1, wherein the spacing between adjacent recesses does not depend on a size of the semiconductor device die.

21. The singulated semiconductor device die of claim 11, wherein the spacing between adjacent recesses does not depend on a size of the semiconductor device die.
